(19) United States
(12) Patent Application Publication
(10) Pub. No.: US 2025/0105011 A1
(43) Pub. Date: Mar. 27, 2025

(54) LASER PROCESSING METHOD AND LASER PROCESSING DEVICE

(71) Applicant: HAMAMATSU PHOTONICS K.K., Hamamatsu-shi, Shizuoka (JP)

(72) Inventors: Takeshi SAKAMOTO, Hamamatsu-shi, Shizuoka (JP); Yo SUGIMOTO, Hamamatsu-shi, Shizuoka (JP); Takafumi OGIWARA, Hamamatsu-shi, Shizuoka (JP); Takashi KURITA, Hamamatsu-shi, Shizuoka (JP); Ryo YOSHIMURA, Hamamatsu-shi, Shizuoka (JP)

(73) Assignee: HAMAMATSU PHOTONICS K.K., Hamamatsu-shi, Shizuoka (JP)

(21) Appl. No.: 18/726,138

(22) PCT Filed: Aug. 22, 2022
(86) PCT No.: PCT/JP2022/031622

§ 371 Date: Jul. 2, 2024

(30) Foreign Application Priority Data
Jan. 28, 2022 (JP) 2022-011672

(51) Int. Cl. H01L 21/268

(52) U.S. Cl. CPC H01L 21/268

(57) ABSTRACT

A laser processing method including: a first step of preparing a wafer having a first region and a second region; a second step of irradiating the street with a predetermined first laser beam; and a third step of irradiating the street with a predetermined second laser beam after the second step, the first laser beam being a laser beam having processing energy for removing a part of the insulating film in the first region to leave the other part, completely removing the metal structure in the second region, and removing a part of the insulating film in the second region to leave the other part, and the second laser beam being a laser beam having processing energy for completely removing the insulating film in the first region and the insulating film in the second region after the second step.

### TECHNICAL FIELD

One aspect of the present invention relates to a laser processing method and a laser processing apparatus.

### BACKGROUND ART

In a wafer including a plurality of functional elements disposed adjacent to each other across a street, there is a case where an insulating film (Low-k film or the like) and a metal structure (a metal pile, a metal pad, or the like) are formed on a surface layer of the street. In such a case, if a modified region is formed in the wafer along a line passing through the street and the wafer is divided into chips for each of the functional elements by extending a fracture from the modified region, the quality of chips may be deteriorated, for example, film peeling may occur in a portion along the street. Therefore, when the wafer is divided into chips for each of the functional elements, grooving processing of removing the surface layer of the street by irradiating the street with a laser beam is performed in some cases.

In the techniques described in Patent Literature 1, processing with multipoint-branched laser beams is performed in order to suppress occurrence of thermal damage on the street due to irradiation with the laser beam. Since the processing with multipoint-branched laser beams is performed, the influence of thermal damage at one processing point is suppressed.

### CITATION LIST

### Patent Literature

Patent Literature 1: Japanese Patent No. 6309341

### SUMMARY OF INVENTION

### Technical Problem

Here, the street may include a region in which the surface layer includes the insulating film and metal structure on the insulating film, and a region in which the surface layer includes only the insulating film (region in which the metal structure is not formed). In such a case, when the street is irradiated with a laser beam under a condition that the metal structure can be reliably removed, there is a possibility that thermal damage occurs in the region where the metal structure is not formed in the surface layer of the street. Such thermal damage causes deterioration in chip quality.

Therefore, an object of one aspect of the present invention is to provide a laser processing method and a laser processing apparatus capable of suppressing deterioration in chip quality.

### Solution to Problem

A laser processing method according to one aspect of the present invention includes: a first step of preparing a wafer including a plurality of functional elements disposed adjacent to each other across a street, the wafer having a first region in which a surface layer of the street includes an insulating film and a second region in which the surface layer includes an insulating film and a metal structure on the insulating film; a second step of irradiating the street with a predetermined first laser beam; and a third step of irradiating the street with a predetermined second laser beam after the second step, the first laser beam being a laser beam having processing energy for removing a part of the insulating film in the first region to leave another part, completely removing the metal structure in the second region, and removing a part of the insulating film in the second region to leave another part in an irradiation range, and the second laser beam being a laser beam having processing energy for completely removing the insulating film in the first region and the insulating film in the second region after the second step in the irradiation range.

In the laser processing method according to one aspect of the present invention, the wafer having, in the surface layer of the street, the first region including the insulating film and the second region including the insulating film and the metal structure on the insulating film is prepared, the street of the wafer is irradiated with the first laser beam, and then the street is irradiated with the second laser beam. The first laser beam is the laser beam having the processing energy for removing a part of the insulating film in the first region to leave the other part, completely removing the metal structure in the second region, removing a part of the insulating film in the second region to leave the other part. In this manner, a part of the insulating film has been removed in both the first region and the second region in a state after the street is irradiated with the first laser beam. Here, a region irradiated with the first laser beam has an uneven shape (frosted glass shape) in the state where a part of the insulating film has been removed by the first laser beam. Such an uneven surface has a low laser beam transmittance. Therefore, even in a case where the second laser beam emitted after the irradiation with the first laser beam is the laser beam having the processing energy for completely removing the insulating film in the first region and the insulating film in the second region, the uneven surface having the low transmittance can suppress passing light in a direction toward a substrate of the wafer made of silicon or the like, and thermal damage of the wafer caused by the laser beam can be suppressed. As described above, it is possible to suppress the thermal damage of the wafer caused by the laser beam and to suppress deterioration in chip quality by the laser processing method according to one aspect of the present invention.

The second laser beam may be a laser beam having processing energy for digging a part of a substrate included in the wafer after the second step. As a result, a part of the substrate is dug by the second laser beam, and it is possible to suppress the occurrence of film peeling in the wafer while reliably performing grooving processing of removing the surface layer.

The second laser beam may be a laser beam having processing energy for carving the substrate by 4 μm or less after the second step. When the amount of digging is set to 4 μm or less, the thermal damage of the wafer caused by the laser beam can be suppressed, and the deterioration in chip quality can be suppressed.

The laser processing method may further include, after the third step, a fourth step of grinding or polishing the substrate to expose a groove formed on the street by irradiation with the second laser beam. According to such a laser processing method, full cutting can be performed by grooving processing without performing a dicing step after laser grooving. As a result, processing can be performed quickly.

A laser processing method according to one aspect of the present invention includes: a first step of preparing a wafer including a plurality of functional elements disposed adjacent to each other across a street, the wafer having a first region in which a surface layer of the street includes an insulating film and a second region in which the surface layer includes an insulating film and a metal structure on the insulating film; a second step of irradiating the street with a laser beam to make the insulating films in the first region and the second region uneven; and a third step of irradiating the street with a laser beam to completely removing the insulating films in the first region and the second region after the second step.

In the laser processing method according to one aspect of the present invention, the wafer having, in the surface layer of the street, the first region including the insulating film and the second region including the insulating film and the metal structure on the insulating film is prepared, the street of the wafer is irradiated with the laser beam to make the insulating films in the first region and the second region uneven, and then the street is irradiated with the second laser beam to completely remove the insulating films in the first region and the second region. An uneven (frosted glass) surface of the insulating film has a low laser beam transmittance. Therefore, even in a case where the laser beam emitted thereafter is the laser beam having the processing energy for completely removing the insulating film in the first region and the insulating film in the second region, the uneven surface having the low transmittance can suppress passing light in a direction toward a substrate of the wafer made of silicon or the like, and thermal damage of the wafer caused by the laser beam can be suppressed. As described above, it is possible to suppress the thermal damage of the wafer caused by the laser beam and to suppress deterioration in chip quality by the laser processing method according to one aspect of the present invention.

A laser processing apparatus according to one aspect of the present invention includes: a support part configured to support a wafer including a plurality of functional elements disposed adjacent to each other across a street, the wafer having a first region in which a surface layer of the street includes an insulating film and a second region in which the surface layer includes an insulating film and a metal structure on the insulating film; an irradiation unit configured to irradiate the street with a laser beam; and a control unit configured to control the irradiation unit, the control unit being configured to execute first control of controlling the irradiation unit in such a manner that the street is irradiated with a predetermined first laser beam, and second control that controls the irradiation unit in such a manner that the street is irradiated with a predetermined second laser beam after the first control, the first laser beam being a laser beam having processing energy for removing a part of the insulating film in the first region to leave another part, completely removing the metal structure in the second region, and removing a part of the insulating film in the second region to leave another part in an irradiation range, and the second laser beam being a laser beam having processing energy for completely removing the insulating film in the first region and the insulating film in the second region after the irradiation with the first laser beam in the irradiation range. In the laser processing apparatus according to one aspect of the present invention, it is possible to suppress thermal damage of the wafer caused by the laser beam and to suppress deterioration in chip quality, which is similar to the laser processing method described above.

A laser processing apparatus according to one aspect of the present invention includes: a support part configured to support a wafer including a plurality of functional elements disposed adjacent to each other across a street, the wafer having a first region in which a surface layer of the street includes an insulating film and a second region in which the surface layer includes an insulating film and a metal structure on the insulating film; an irradiation unit configured to irradiate the street with a laser beam; and a control unit configured to control the irradiation unit, the control unit being configured to execute first control of controlling the irradiation unit in such a manner that the street is irradiated with the laser beam to make the insulating films in the first region and the second region uneven, and second control of controlling the irradiation unit in such a manner that the street is irradiated with the laser beam to completely remove the insulating films in the first region and the second region after the first control. In the laser processing apparatus according to one aspect of the present invention, it is possible to suppress thermal damage of the wafer caused by the laser beam and to suppress deterioration in chip quality, which is similar to the laser processing method described above.

### Advantageous Effects of Invention

According to one aspect of the present invention, it is possible to suppress the deterioration in the chip quality.

### BRIEF DESCRIPTION OF DRAWINGS

FIG. 1 is a configuration diagram illustrating a laser processing apparatus according to an embodiment.

FIG. 2 is a plan view of a wafer processed by the laser processing apparatus illustrated in FIG. 1.

FIG. 3 is a cross-sectional view illustrating a part of the wafer illustrated in FIG. 2.

FIG. 4 is a plan view of a part of a street illustrated in FIG. 2.

FIG. 5 is a diagram for describing generation of a heat-affected zone (HAZ) by grooving processing.

FIG. 6 is a diagram for describing the grooving processing according to the present embodiment.

FIG. 7 is a diagram for describing the principle of suppressing the generation of the HAZ.

FIG. 8 is a view for describing an example of condition setting in a case where a pad region is removed (dug) in one pass.

FIG. 9 is a view illustrating an example of condition setting in a case where a pad region is removed (dug) in two passes.

FIG. 10 is a view for describing an example of condition setting in the case where the pad region is removed (dug) in two passes.

FIG. 11 is a view illustrating conditions of a test regarding a relationship between a depth of laser grooving and chip strength.

FIG. 12 is a view illustrating conditions of the test regarding the relationship between the depth of laser grooving and the chip strength.

FIG. 13 is a view illustrating results of the test regarding the relationship between the depth of laser grooving and the chip strength.

FIG. 14 is a flowchart of a laser processing method according to an embodiment.

FIG. 15 is a diagram for describing a laser processing method according to a modification.

FIG. 16 is a flowchart of the laser processing method according to the modification.

FIG. 17 is a diagram for describing a laser processing method according to another modification.

### DESCRIPTION OF EMBODIMENTS

Hereinafter, embodiments of the present invention will be described in detail with reference to the drawings. Note that, in the drawings, identical or corresponding parts are denoted by identical reference signs, and redundant description will be omitted.

### [Configuration of Laser Processing Apparatus]

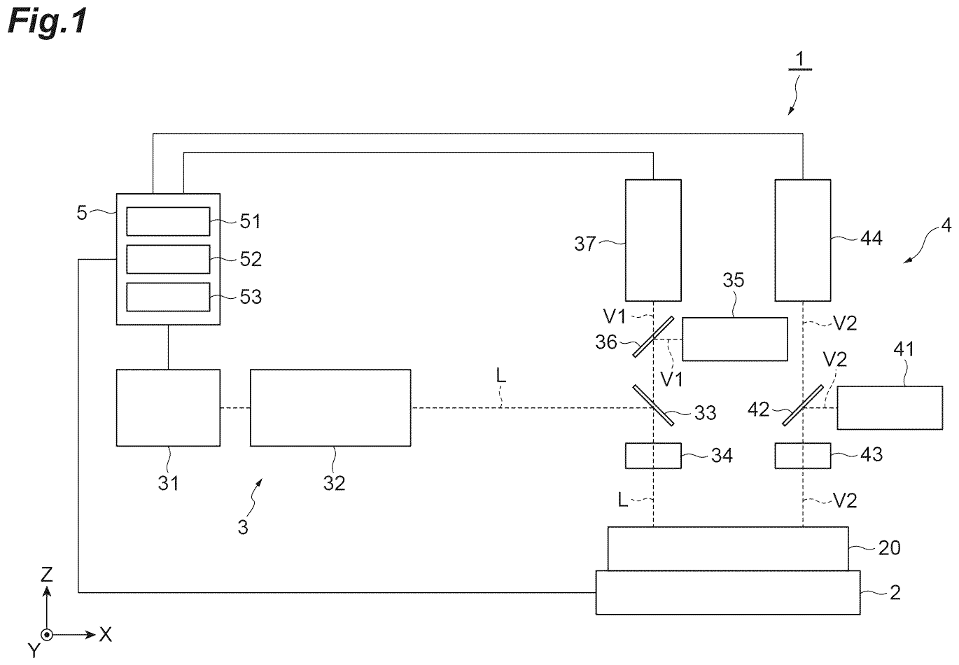

As illustrated in FIG. 1, a laser processing apparatus 1 includes a support part 2, an irradiation unit 3, an imaging unit 4, and a control unit 5. The laser processing apparatus 1 is a apparatus that performs grooving processing of removing a surface layer of a street of a wafer 20 by irradiating the street (details will be described later) of the wafer 20 with a laser beam L. In the following description, three directions perpendicular to each other are referred to as an X direction, a Y direction, and a Z direction, respectively. As an example, the X direction is a first horizontal direction, the Y direction is a second horizontal direction perpendicular to the first horizontal direction, and the Z direction is a vertical direction.

The support part 2 supports the wafer 20. The support part 2 holds the wafer 20 such that a front surface of the wafer 20 including the street faces the irradiation unit 3 and the imaging unit 4, for example, by sucking a film (not illustrated) attached to the wafer 20. As an example, the support part 2 can move along the X direction and the Y direction, respectively, and can rotate around an axis parallel to the Z direction as a center line.

The irradiation unit 3 irradiates the street of the wafer 20 supported by the support part 2 with the laser beam L. The irradiation unit 3 includes a light source 31, a shaping optical system 32, a dichroic mirror 33, and a light condenser 34. The light source 31 emits the laser beam L. The shaping optical system 32 adjusts the laser beam L emitted from the light source 31. As an example, the shaping optical system 32 includes at least one of an attenuator that adjusts an output of the laser beam L, a beam expander that expands a diameter of the laser beam L, and a spatial light modulator that modulates a phase of the laser beam L. When the spatial light modulator is included, the shaping optical system 32 may include an imaging optical system constituting a double telecentric optical system in which a modulation surface of the spatial light modulator and an entrance pupil surface of the light condenser 34 are in an imaging relationship. The dichroic mirror 33 reflects the laser beam L emitted from the shaping optical system 32 to be incident on the light condenser 34. The light condenser 34 condenses the laser beam L reflected by the dichroic mirror 33 on the street of the wafer 20 supported by the support part 2.

The irradiation unit 3 further includes a light source 35, a half mirror 36, and an imaging element 37. The light source 35 emits visible light V1. The half mirror 36 reflects the visible light V1 emitted from the light source 35 to be incident on the light condenser 34. The dichroic mirror 33 transmits the visible light V1 between the half mirror 36 and the light condenser 34. The light condenser 34 condenses the visible light V1 reflected by the half mirror 36 on the street of the wafer 20 supported by the support part 2. The imaging element 37 detects the visible light V1 reflected by the street of the wafer 20 and transmitted through the light condenser 34, the dichroic mirror 33, and the half mirror 36. In the laser processing apparatus 1, the control unit 5 moves the light condenser 34 along the Z direction based on a detection result by the imaging element 37, for example, such that a condensing point of the laser beam L is located on the street of the wafer 20.

The imaging unit 4 acquires image data of the street of the wafer 20 supported by the support part 2. The imaging unit 4 includes a light source 41, a half mirror 42, a light condenser 43, and an imaging element 44. The light source 41 emits visible light V2. The half mirror 42 reflects the visible light V2 emitted from the light source 41 to be incident on the light condenser 43. The light condenser 43 condenses the visible light V2 reflected by the half mirror 42 on the street of the wafer 20 supported by the support part 2. The imaging element 44 detects the visible light V2 reflected by the street of the wafer 20 and transmitted through the light condenser 43 and the half mirror 42.

The control unit 5 controls the operation of each part in the laser processing apparatus 1. The control unit 5 controls, for example, the irradiation unit 3. The control unit 5 includes a processing unit 51, a storage unit 52, and an input reception unit 53. The processing unit 51 is a computer apparatus including a processor, a memory, a storage, a communication device, and the like. In the processing unit 51, the processor executes software (program) read into the memory or the like, and controls reading and writing of data in the memory and the storage, and communication by a communication device. The storage unit 52 is, for example, a hard disk or the like, and stores various types of data. The input reception unit 53 is an interface unit that receives inputs of various types of data from an operator. As an example, the input reception unit 53 is at least one of a keyboard, a mouse, and a graphical user interface (GUI).

### [Configuration of Wafer]

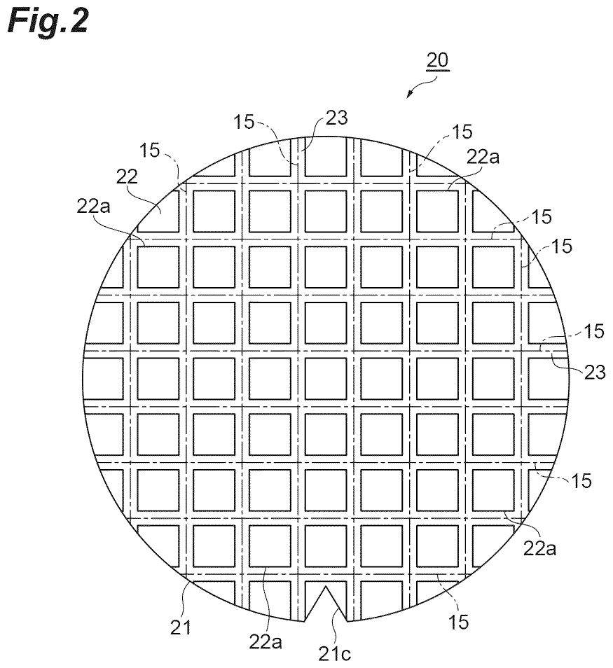

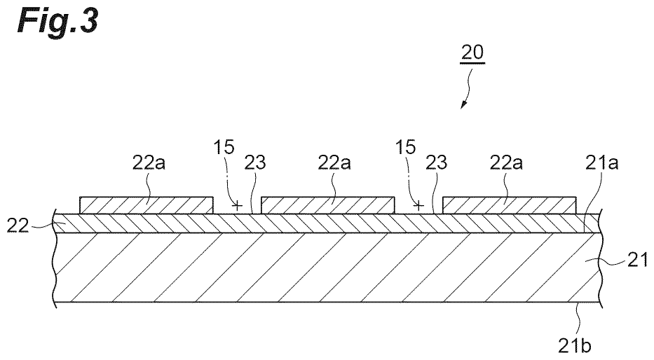

As illustrated in FIGS. 2 and 3, the wafer 20 includes a semiconductor substrate 21 and a functional element layer 22. The semiconductor substrate 21 has a front surface 21a and a back surface 21b. The semiconductor substrate 21 is, for example, a silicon substrate. A notch 21c indicating a crystal orientation is provided in the semiconductor substrate 21. The semiconductor substrate 21 may be provided with an orientation flat instead of the notch 21c. The functional element layer 22 is formed on the front surface 21a of the semiconductor substrate 21. The functional element layer 22 includes a plurality of functional elements 22a. The plurality of functional elements 22a are two-dimensionally disposed along the front surface 21a of the semiconductor substrate 21. Each of the functional elements 22a is, for example, a light receiving element such as a photodiode, a light emitting element such as a laser diode, a circuit element such as a memory, or the like. Each of the functional elements 22a may be configured three-dimensionally by stacking a plurality of layers.

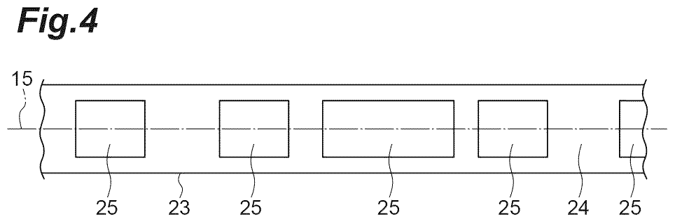

A plurality of streets 23 are formed on the wafer 20. The plurality of streets 23 are regions exposed to the outside between the adjacent functional elements 22a. That is, the plurality of functional elements 22a are disposed adjacent to each other across the street 23. As an example, the plurality of streets 23 extend in a lattice shape so as to pass between the adjacent functional elements 22a with respect to the plurality of functional elements 22a arranged in a matrix. As illustrated in FIG. 4, an insulating film 24 and a plurality of metal structures 25 are formed on a surface layer of the street 23. The insulating film 24 is, for example, a low-k film or the like. The metal structure 25 is, for example, a metal pad made of aluminum or the like.

As illustrated in FIGS. 2 and 3, the wafer 20 is planned to be cut (that is, divided into chips for each of the functional elements 22a) for each of the functional elements 22a along each of a plurality of lines 15. The lines 15 passes through the streets 23, respectively, when viewed from a thickness direction of the wafer 20. As an example, the lines 15 extends to pass through the centers of the streets 23, respectively, when viewed from the thickness direction of the wafer 20. Each of the lines 15 is a virtual line set on the wafer 20 by the laser processing apparatus 1. Each of the lines 15 may be a line actually drawn on the wafer 20.

### [Operation of Laser Processing Apparatus and Laser Processing Method]

The laser processing apparatus 1 performs grooving processing of irradiating each of the streets 23 with the laser beam L and removing the surface layer of each of the streets 23. Specifically, the control unit 5 controls the irradiation unit 3 such that each of the streets 23 of the wafer 20 supported by the support part 2 is irradiated with the laser beam L, and the control unit 5 controls the support part 2 such that the laser beam L relatively moves along each of the streets 23.

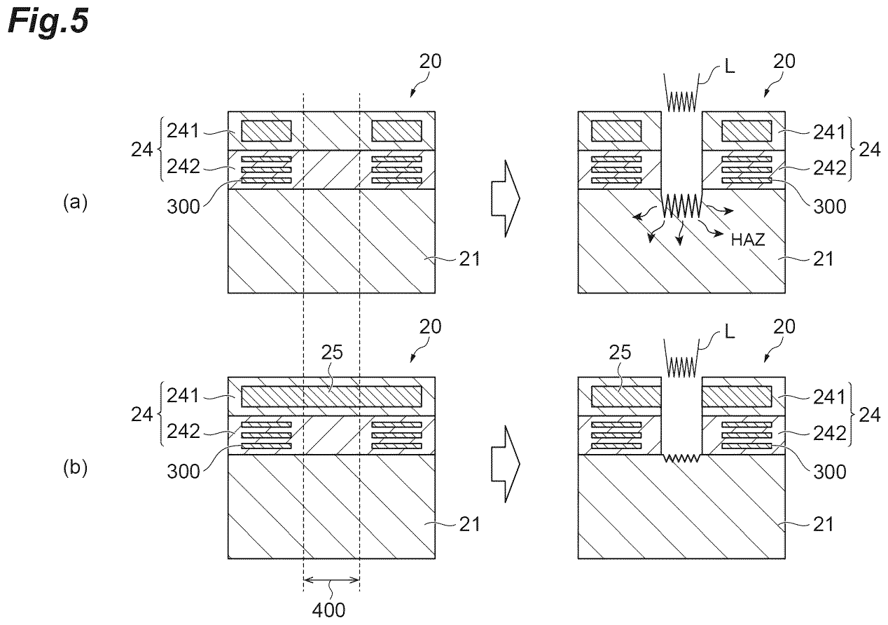

For example, in grooving processing in the case of performing blade dicing, it is necessary to completely remove the surface layer of the street 23 from a dicing line. Here, the surface layer of the street 23 includes a region (hereinafter, sometimes referred to as a first region) including only the insulating film 24 and a region (hereinafter, sometimes referred to as a second region) including the insulating film 24 and the metal structure 25 on the insulating film 24. For example, a surface layer (region of a dicing street 400) of the street 23 of the wafer 20 illustrated in the left diagram of FIG. 5(a) includes only a low-k film 242 and a SiN/SiO2 film 241, which correspond to the insulating film 24, and indicates the first region. In addition, a surface layer (region of the dicing street 400) of the street 23 of the wafer 20 illustrated in the left diagram of FIG. 5(b) includes the low-k film 242 and the SiN/SiO2 film 241, which correspond to the insulating film 24, and the metal structure 25 (metal pad) on the insulating film 24, and indicates the second region. When the wafer 20 having the first region and the second region is processed under common grooving processing conditions regardless of the region, thermal damage of the wafer 20 may become a problem.

That is, in order to completely remove the surface layer of the street 23 in any region of the wafer 20, it is necessary to set processing energy of the laser beam L for the grooving processing such that the surface layer is dug up to an interface of the semiconductor substrate 21 in the second region including the insulating film 24 and the metal structure 25 on the insulating film 24 (see the right diagram of FIG. 5(b)). Since an absorption rate of a laser wavelength is larger in the metal structure 25 than in the insulating film 24, most of the energy is absorbed by the metal structure 25 in the second region. Therefore, it is necessary to increase the processing energy of the laser beam L in order to also remove the insulating film 24 below the metal structure 25. However, when the grooving processing is performed on the first region including only the insulating film 24 with the laser beam L whose processing energy has been increased in this manner, the energy is excessive in the first region, the semiconductor substrate 21 is excessively dug to generate a heat-affected zone (HAZ) as illustrated in the right diagram of FIG. 5(a), and a decrease in strength of the wafer 20 may be a problem due to the thermal damage of the wafer 20.

The example illustrated in FIG. 5 illustrates the generation of the HAZ in a case where conditions of the wafer 20 and conditions of the laser grooving are set as follows, for example.

### (Conditions of Wafer 20)

Wafer size: 12 inch, Wafer thickness: 300 μm, Chip size: 5 mm, Width of dicing street 400: 60 μm, Pattern thickness (thickness of insulating film 24): 8 μm, and Thickness of metal structure 25: 1 μm.

### (Conditions of Laser Grooving)

Forming groove having width of 55 μm for blade dicing, Wavelength of laser beam L: 515 μm, Pulse width: 600 fs, Condensing position: Device surface, Number of branches: 21-point branches, Pulse pitch: 0.5 μm, Processing energy: 9.9 μJ, Fluence/point: 0.85 J/cm², and Number of scans: 2 passes.

Here, Fluence/point indicates pulse energy per predetermined area, and indicates a value at each branching point (one point). Note that the low-k film 242, which is the insulating film 24, is provided with, for example, a wiring 300 as illustrated in FIG. 5.

In order to solve the above-described problem, a laser processing method according to the present embodiment divides irradiation with the street 23 with a laser beam in the grooving processing into two steps. Specifically, the laser processing method performed by the laser processing apparatus 1 includes a step (second step) of irradiating the street 23 with a predetermined first laser beam, and a step (third step) of irradiating the street 23 with a predetermined second laser beam after the irradiating step with the first laser beam. In order to perform these steps, the control unit 5 is configured to execute first control of controlling the irradiation unit 3 such that the street 23 is irradiated with the predetermined first laser beam and second control of controlling the irradiation unit 3 such that the street 23 is irradiated with the predetermined second laser beam after the first control. Then, the first laser beam is a laser beam having processing energy for removing a part of the insulating film 24 in the first region to leave the other part, completely removing the metal structure 25 in the second region, and removing a part of the insulating film 24 in the second region to leave the other part in an irradiation range. In addition, the second laser beam is a laser beam having processing energy for completely removing the insulating film 24 in the first region and the insulating film 24 in the second region after being irradiated with the first laser beam in the irradiation range.

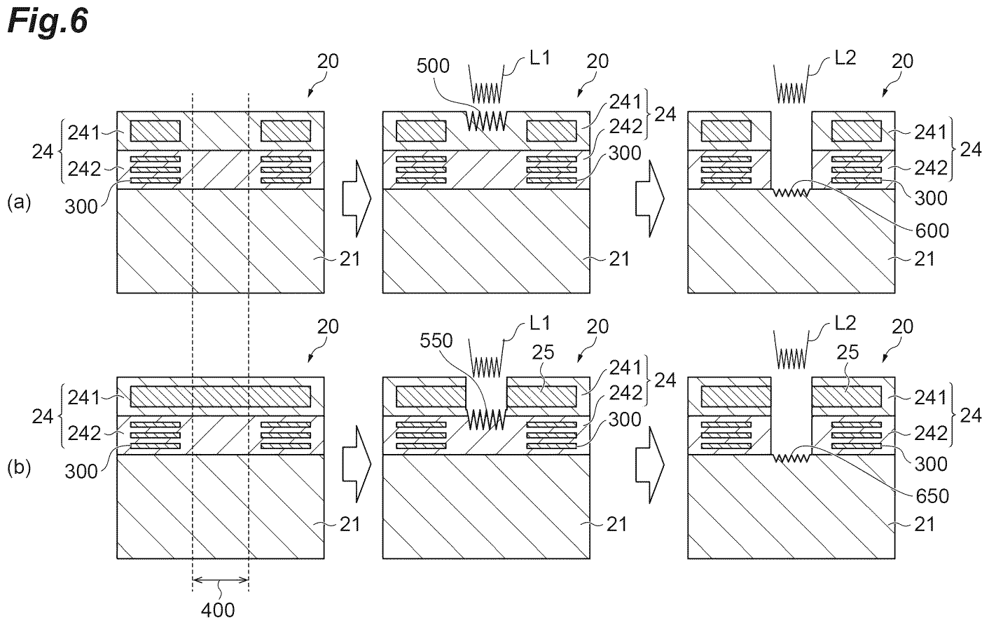

FIG. 6 is a diagram for describing the grooving processing according to the present embodiment. FIG. 6(a) illustrates irradiation of a first laser beam L1 (see the central diagram of FIG. 6(a)) and irradiation of a second laser beam L2 (see the right diagram of FIG. 6(a)) in the first region. FIG. 6(b) illustrates irradiation with the first laser beam L1 (see the central diagram of FIG. 6(b)) and irradiation with the second laser beam L2 (see the right diagram of FIG. 6(b)) in the second region.

As illustrated in the central diagram of FIG. 6(a), the first laser beam L1 has processing energy for removing a part of the insulating film 24 in the first region to leave the other part in the irradiation range. In addition, as illustrated in the central diagram of FIG. 6(b), the first laser beam L1 has processing energy for completely removing the metal structure 25 in the second region and removing a part of the insulating film 24 in the second region to leave the other part in the irradiation range. Here, the expression “removing a part of the insulating film 24 to leave the other part” means removing not the entire insulating film 24 but only a part thereof and leaving a part other than the removed part in the irradiation range. In addition, the expression “completely removing the metal structure 25” means that the entire metal structure 25 is removed in the irradiation range. Note that the expression “completely removing the metal structure 25” may include removing substantially the entire metal structure 25 to leave the metal structure 25 in a small amount to such an extent that its function can be ignored.

As illustrated in the central diagram of FIG. 6(a), in the first region after being irradiated with the first laser beam L1, a part of the insulating film 24 (here, a part of the SiN/SiO2 film 241) has been removed by the first laser beam L1, and a surface irradiated with the first laser beam L1 has formed a frosted glass surface 500 having an uneven shape (frosted glass shape). In addition, as illustrated in the central diagram of FIG. 6(b), in the second region after being irradiated with the first laser beam L1, the metal structure 25 has been completely removed by the first laser beam L1, a part of the insulating film 24 (here, the entire SiN/SiO2 film 241 and a part of the low-k film 242) has been removed, and a surface irradiated with the first laser beam L1 has formed a frosted glass surface 550 having an uneven shape (frosted glass shape). In this manner, the irradiating step with the first laser beam L1 (second step) is a step of irradiating the street 23 with the first laser beam L1 to make the insulating films 24 in the first region and the second region uneven. That is, the control unit 5 executes the first control of controlling the irradiation unit 3 such that the street 23 is irradiated with the first laser beam L1 to make the insulating films 24 in the first region and the second region uneven. The frosted glass surface 500 and the frosted glass surface 550 will be described later.

As illustrated in the right diagram of FIG. 6(a), the second laser beam L2 has processing energy for completely removing the insulating film 24 in the first region after being irradiated with the first laser beam L1 in the irradiation range. In addition, as illustrated in the right diagram of FIG. 6(b), the second laser beam L2 has processing energy for completely removing the insulating film 24 in the second region after being irradiated with the first laser beam L1 in the irradiation range. Here, the expression “completely removing the insulating film 24” means removing the entire insulating film 24 in the irradiation range. Note that the expression “completely removing the insulating film 24” may include removing substantially the entire insulating film 24 to leave the insulating film 24 in a small amount to such an extent that its function can be ignored.

As illustrated in the right diagram of FIG. 6(a) and the right diagram of FIG. 6(b), the second laser beam L2 has processing energy for digging a part of the semiconductor substrate 21 of the wafer 20 after irradiation with the first laser beam L1. That is, both an irradiation plane 600 of the second laser beam L2 in the first region (see FIG. 6(a)) and an irradiation plane 650 of the second laser beam L2 in the second region (see FIG. 6(b)) reach the semiconductor substrate 21. In this manner, the irradiating step with the second laser beam L2 (third step) is a step of irradiating the street 23 with the laser beam L2 to completely remove the insulating films 24 in the first region and the second region. That is, after the first control described above, the control unit 5 executes the second control of controlling the irradiation unit 3 such that the street 23 is irradiated with the second laser beam L2 to completely remove the insulating films 24 in the first region and the second region. The second laser beam L2 may have processing energy for carving the semiconductor substrate 21 of the wafer 20 by 4 μm or less after the irradiation with the first laser beam L1. When the amount of digging is set to 4 μm or less in this manner, thermal damage of the wafer 20 caused by the second laser beam L2 can be suppressed, and deterioration in chip quality can be suppressed.

The grooving processing in FIG. 6 is performed, for example, under the following conditions of the wafer 20 and laser grooving.

### (Conditions of Wafer 20)

Wafer size: 12 inch, Wafer thickness: 300 μm, Chip size: 5 mm, Width of dicing street 400: 60 μm, Pattern thickness (thickness of insulating film 24): 8 μm, and Thickness of metal structure 25: 1 μm.

(Conditions of Laser Grooving Processing in Irradiating Step with First Laser Beam L1 (Second Step))

Forming groove having width of 55 μm for blade dicing, Wavelength of first laser beam L1: 515 μm, Pulse width: 600 fs, Condensing position: Device surface, Number of branches: 21-point branches, Pulse pitch: 0.5 μm, Processing energy: 4.1 μJ, Fluence/point: 0.35 J/cm², and Number of scans: 1 passes.

(Conditions of Laser Grooving Processing in Irradiating Step with Second Laser Beam L2 (Third Step))

Forming groove having width of 55 μm for blade dicing, Wavelength of second laser beam L2: 515 μm, Pulse width: 600 fs, Condensing position: Device surface, Number of branches: 21-point branches, Pulse pitch: 0.5 μm, Processing energy: 9.9 μJ, Fluence/point: 0.85 J/cm², and Number of scans: 2 passes.

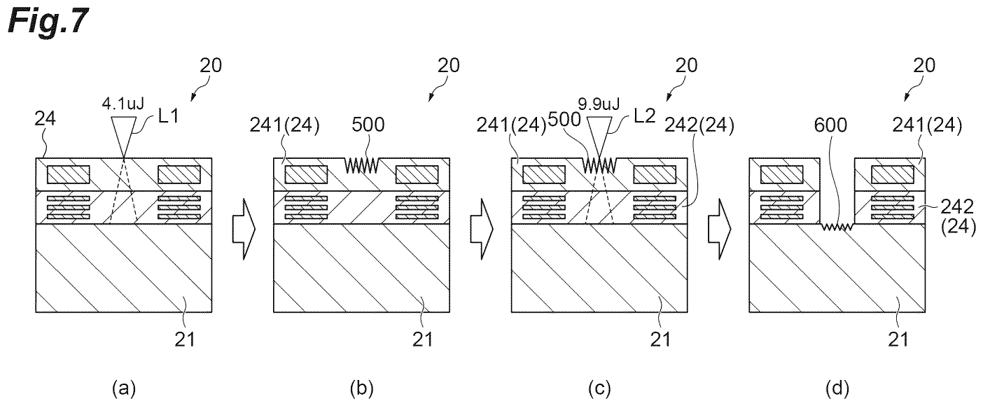

Next, the principle that the generation of the HAZ can be suppressed by the grooving processing illustrated in FIG. 6 will be described with reference to FIG. 7. FIG. 7 is a diagram for describing the principle of suppressing the generation of the HAZ. FIG. 7 illustrates steps of grooving processing in the first region of the wafer 20.

As illustrated in FIG. 7(a), it is assumed that irradiation is performed with the first laser beam L1 having processing energy (for example, 4.1 μJ) for removing a part of the insulating film 24 in the first region to leave the other part. Since such first laser beam L1 has weak processing energy, the generation of the HAZ in the semiconductor substrate 21 due to passing light is suppressed. Then, as illustrated in FIG. 7(b), a part (here, a part of the SiN/SiO2 film 241) of the insulating film 24 in the vicinity of a condensing point is removed by the first laser beam L1, and a surface irradiated with the first laser beam L1 becomes the frosted glass surface 500 having an uneven shape (frosted glass shape). The frosted glass surface 500 here is a geometric surface whose direction randomly changes with respect to a normal line of an optical surface. In such a frosted glass surface 500, light is randomly refracted or scattered, so that a laser beam transmittance decreases. Alternatively, in such a frosted glass surface 500, a laser beam absorption rate increases due to a shape change, discoloration, and the like. Therefore, the laser beam with which the frosted glass surface 500 is irradiated hardly reaches the semiconductor substrate 21.

Then, as illustrated in FIG. 7(c), the frosted glass surface 500, which has been already irradiated with the first laser beam L1, is irradiated with the second laser beam L2 having processing energy (for example, 9.9 μJ) for completely removing the insulating film 24 in the first region. Such a second laser beam L2 is originally a laser beam having processing energy with which a dug depth in the semiconductor substrate 21 increases and the HAZ is generated in the semiconductor substrate 21 (see the right diagram of FIG. 5(a)). However, since the frosted glass surface 500 having a low laser beam transmittance is irradiated with the second laser beam L2, the generation of the HAZ due to excessive digging of the semiconductor substrate 21 with the second laser beam L2 as illustrated in FIG. 7(d) is suppressed. Specifically, a dug depth with the second laser beam L2 is, for example, 4 μm or less.

Here, the second region includes the insulating film 24 and the metal structure 25 on the insulating film 24, and is different from the first region including only the insulating film 24, but can be subjected to grooving under the same grooving processing conditions (that is, the first laser beam L1 and the second laser beam L2) as those for the grooving processing of the first region. That is, when the second region is irradiated with the first laser beam L1 having relatively weak processing energy, the metal structure 25 having a high absorption rate is relatively easily removed even if the processing energy is weak. Therefore, the second region can also be brought into a state in which (the metal structure 25 is completely removed and) a part of the insulating film 24 in the second region is removed by the first laser beam L1 and the other part is left, that is, a state in which the frosted glass surface 550 (see the central diagram in FIG. 6(b)) is formed. Then, the frosted glass surface 550, which has been already irradiated with the first laser beam L1, is irradiated with the second laser beam L2 having processing energy (for example, 9.9 μJ) for completely removing the insulating film 24 in the second region, whereby the insulating film 24 can be appropriately removed while suppressing the generation of the HAZ similarly to the first region.

Next, condition setting of the grooving processing will be described in detail. The condition setting here means setting (condition setting) of Fluence/point of each of the first laser beam L1 and the second laser beam L2. As described above, Fluence/point of each of the first laser beam L1 and the second laser beam L2 is set so as to satisfy the conditions in the grooving processing of both the first region and the second region. That is, Fluence/point of the first laser beam L1 is set such so as to remove a part of the insulating film 24 in the first region to leave the other part, completely remove the metal structure 25 in the second region, and remove a part of the insulating film 24 in the second region to leave the other part in the irradiation range. In addition, Fluence/point of the second laser beam L2 is set to completely remove the insulating film 24 of the first region and the insulating film 24 of the second region and suppress the generation of the HAZ in the irradiation range.

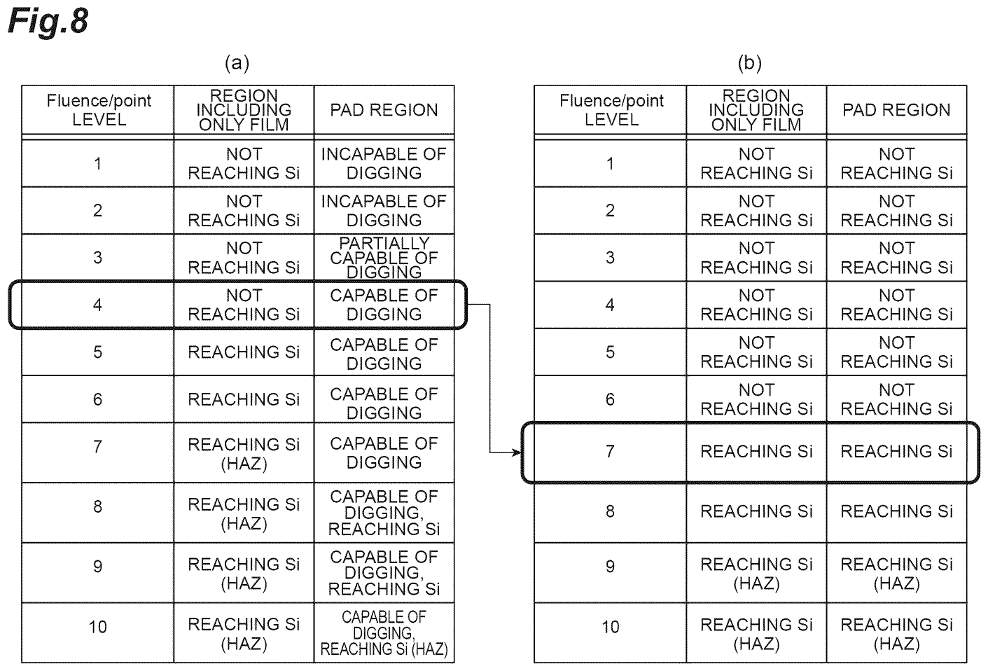

FIG. 8 is a view for describing an example of the condition setting in a case where a pad region where the metal structure 25 is formed is removed (dug) in one pass. In FIG. 8, “Not reaching Si” indicates a state in which a part of the insulating film 24 is removed and the other part remains, “Reaching Si” indicates a state in which the insulating film 24 is completely removed and the HAZ is not generated, and “Reaching Si (HAZ)” indicates a state in which the insulating film 24 is completely removed and the HAZ is generated. In addition, in FIG. 8, “Not dug” indicates a state in which the metal structure 25 is not removed at all, and “Partially dug” indicates a state in which a part of the metal structure 25 is removed, “Dug” indicates a state in which the metal structure 25 is completely removed, a part of the insulating film 24 is removed, and the other part remains, “Dug, reaching Si” indicates a state in which the metal structure 25 is completely removed, the insulating film 24 is completely removed, and the HAZ is not generated, and “Dug, reaching Si (HAZ)” indicates a state in which the metal structure 25 is completely removed, the insulating film 24 is completely removed, and the HAZ is generated. FIG. 8(a) is a view for describing the condition setting of the first laser beam L1. FIG. 8(b) is a view for describing the condition setting of the second laser beam L2.

FIG. 8(a) illustrates a state of the first region (described as “Region including only film” in FIG. 8) and a state of the second region (described as “Pad region” in FIG. 8) after grooving processing of each Fluence/point level with respect to the first laser beam L1. Note that an increase in Fluence/point level means that the value of Fluence/point increases. As described above, Fluence/point of the first laser beam L1 is set such so as to remove a part of the insulating film 24 in the first region to leave the other part, completely remove the metal structure 25 in the second region, and remove a part of the insulating film 24 in the second region to leave the other part in the irradiation range. Therefore, the Fluence/point level of the first laser beam L1 is set to 4 in the example illustrated in FIG. 8(a).

FIG. 8(b) illustrates a state of the first region (described as “Region including only film” in FIG. 8) and a state of the second region (described as “Pad region” in FIG. 8) after grooving processing of each Fluence/point level with respect to the second laser beam L2. Note that results of FIG. 8(b) illustrate a state in which the wafer 20 after being subjected to the grooving processing with the first laser beam L1 at the Fluence/point level set based on FIG. 8(a) is subjected to the grooving processing with the second laser beam L2 at each Fluence/point level. As described above, Fluence/point of the second laser beam L2 is set to “completely remove the insulating film 24 of the first region and the insulating film 24 of the second region and suppress the generation of the HAZ in the irradiation range”. Therefore, the Fluence/point level of the second laser beam L2 is set to 7 in the example illustrated in FIG. 8(b). Note that a desired result is obtained even when the Fluence/point level of the second laser beam L2 is set to 8, it is preferable that the minimum level is selected as the Fluence/point level.

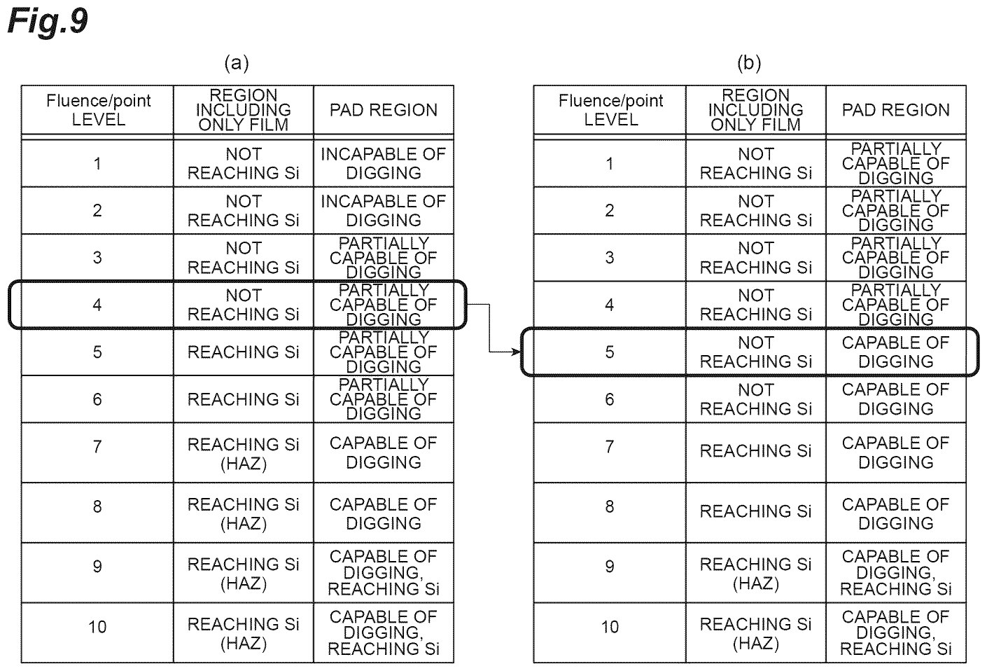

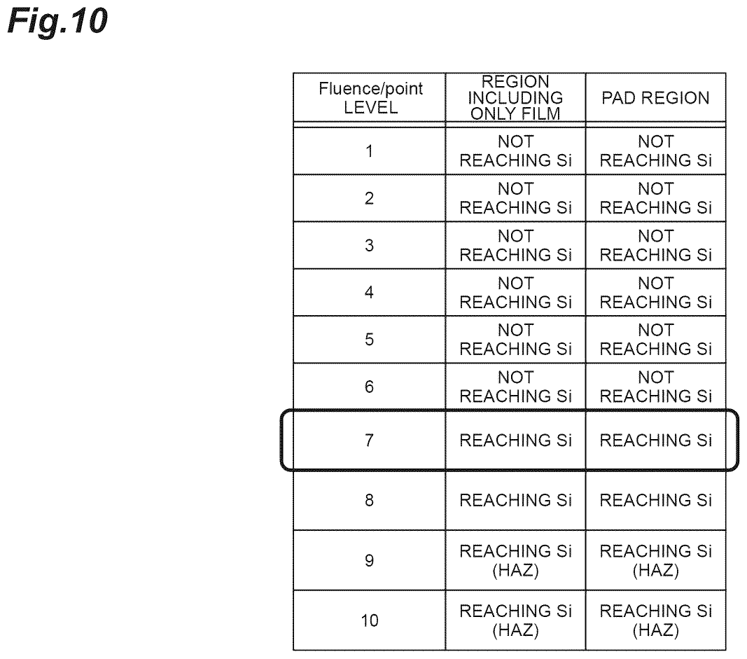

FIGS. 9 and 10 are views for describing examples of the condition setting in a case where the pad region where the metal structure 25 is formed is removed (dug) in two passes. In FIGS. 9 and 10, “Not reaching Si” indicates a state in which a part of the insulating film 24 is removed and the other part remains, “Reaching Si” indicates a state in which the insulating film 24 is completely removed and the HAZ is not generated, and “Reaching Si (HAZ)” indicates a state in which the insulating film 24 is completely removed and the HAZ is generated. In addition, in FIGS. 9 and 10, “Not dug” indicates a state in which the metal structure 25 is not removed at all, and “Partially dug” indicates a state in which a part of the metal structure 25 is removed, “Dug” indicates a state in which the metal structure 25 is completely removed, a part of the insulating film 24 is removed, and the other part remains, “Dug, reaching Si” indicates a state in which the metal structure 25 is completely removed, the insulating film 24 is completely removed, and the HAZ is not generated, and “Dug, reaching Si (HAZ)” indicates a state in which the metal structure 25 is completely removed, the insulating film 24 is completely removed, and the HAZ is generated. FIG. 9(a) is a view for describing condition setting for the first pass of the first laser beam L1, FIG. 9(b) is a view for describing condition setting for the second pass of the first laser beam L1, and FIG. 10 is a view for describing condition setting of the second laser beam L2.

FIG. 9(a) illustrates a state of the first region (described as “Region including only film” in FIG. 8) and a state of the second region (described as “Pad region” in FIG. 8) after grooving processing of each Fluence/point level with respect to the first laser beam L1 of the first pass. Since the pad region is removed in two passes, the Fluence/point level in the first pass of the first laser beam L1 is set to 4 (only a part of the metal structure 25 is removed) in the example illustrated in FIG. 9(a).

FIG. 9(b) illustrates a state of the first region (described as “Region including only film” in FIG. 8) and a state of the second region (described as “Pad region” in FIG. 8) after grooving processing of each Fluence/point level with respect to the first laser beam L1 of the second pass. Note that results of FIG. 9(b) illustrate a state where the wafer 20 on which the grooving processing has been performed with the first laser beam L1 in the first pass at the Fluence/point level set based on FIG. 9(a) is subjected to the grooving processing with the first laser beam L1 in the second pass at each Fluence/point level. As described above, Fluence/point of the first laser beam L1 is set such so as to remove a part of the insulating film 24 in the first region to leave the other part, completely remove the metal structure 25 in the second region, and remove a part of the insulating film 24 in the second region to leave the other part in the irradiation range. Therefore, the Fluence/point level of the second pass of the first laser beam L1 is set to 5 in the example illustrated in FIG. 9(b).

FIG. 10 illustrates a state of the first region (described as “Region including only film” in FIG. 8) and a state of the second region (described as “Pad region” in FIG. 8) after grooving processing of each Fluence/point level with respect to the second laser beam L2. Note that results of FIG. 10 illustrate a state in which the wafer 20 after being subjected to the grooving processing with the first laser beam L1 of the second pass at the Fluence/point level set based on FIG. 9(b) is subjected to the grooving processing with the second laser beam L2 at each Fluence/point level. As described above, Fluence/point of the second laser beam L2 is set to “completely remove the insulating film 24 of the first region and the insulating film 24 of the second region and suppress the generation of the HAZ in the irradiation range”. Therefore, the Fluence/point level of the second laser beam L2 is set to 7 in the example illustrated in FIG. 10. Note that a desired result is obtained even when the Fluence/point level of the second laser beam L2 is set to 8, it is preferable that the minimum level is selected as the Fluence/point level.

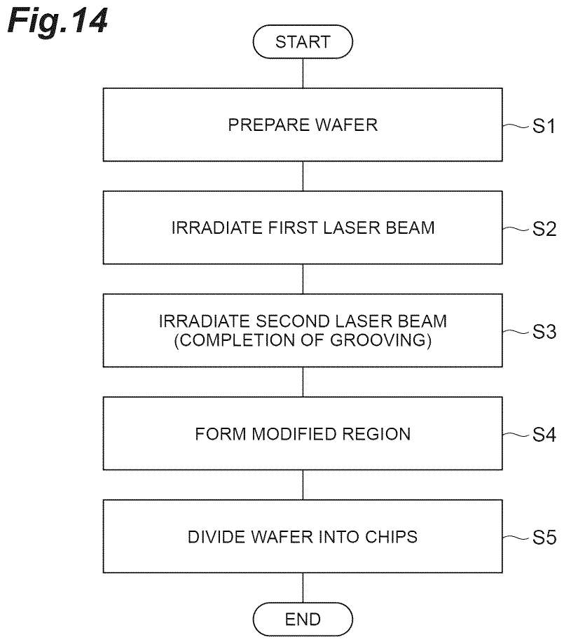

Next, the laser processing method will be described with reference to a flowchart of FIG. 14. First, the wafer 20 is prepared (step S1, a first step). As described above, the wafer 20 is a wafer including the plurality of functional elements 22a disposed adjacent to each other across the street 23, the wafer having a first region in which a surface layer of the street 23 includes the insulating film 24 and a second region in which the surface layer includes the insulating film 24 and the metal structure 25 on the insulating film 24.

Subsequently, the street 23 is irradiated with the predetermined first laser beam L1 by the laser processing apparatus 1 (step S2, the second step). As described above, the first laser beam L1 is a laser beam having processing energy for removing a part of the insulating film 24 in the first region to leave the other part, completely removing the metal structure 25 in the second region, and removing a part of the insulating film 24 in the second region to leave the other part in an irradiation range.

Subsequently, the street 23 is irradiated with the predetermined second laser beam L2 by the laser processing apparatus 1 (step S3, the third step). As described above, the second laser beam L2 is a laser beam having processing energy for completely removing the insulating film 24 in the first region and the insulating film 24 in the second region after the second step in the irradiation range. The grooving processing is completed by the third step.

Subsequently, for example, the wafer 20 is irradiated with a laser beam along each of the lines 15 by an SD processing apparatus (not illustrated) different from the laser processing apparatus 1, a modified region 11 is formed inside the wafer 20 along each of the lines 15 (step S4). Finally, an expanded film (not illustrated) is expanded by an expanding apparatus (not illustrated) to extend a crack in the thickness direction of the wafer 20 from the modified region 11 formed inside the semiconductor substrate 21 along each of the lines 15, whereby the wafer 20 is divided into chips for each of the functional elements 22a (step S5).

### Actions and Effects

A laser processing method according to the present embodiment includes: a first step of preparing the wafer 20 including the plurality of functional elements 22a disposed adjacent to each other across the street 23, the wafer 20 having a first region in which a surface layer of the street 23 includes the insulating film 24 and a second region in which the surface layer includes the insulating film 24 and the metal structure 25 on the insulating film 24; a second step of irradiating the street 23 with the predetermined first laser beam L1; and a third step of irradiating the street 23 with the predetermined second laser beam L2 after the second step, the first laser beam L1 being a laser beam having processing energy for removing a part of the insulating film 24 in the first region to leave the other part, completely removing the metal structure 25 in the second region, and removing a part of the insulating film 24 in the second region to leave the other part in an irradiation range, and the second laser beam L2 being a laser beam having processing energy for completely removing the insulating film 24 in the first region and the insulating film 24 in the second region after the second step in the irradiation range.

In the laser processing method according to the present embodiment, the wafer 20 having, in the surface layer of the street 23, the first region including the insulating film 24 and the second region including the insulating film 24 and the metal structure 25 on the insulating film 24 is prepared, and the street 23 of the wafer 20 is irradiated with the first laser beam L1, and then the street 23 is irradiated with the second laser beam L2. The first laser beam L1 is the laser beam having the processing energy for removing a part of the insulating film 24 in the first region to leave the other part, completely removing the metal structure 25 in the second region, removing a part of the insulating film 24 in the second region to leave the other part. In this manner, a part of the insulating film 24 is removed in both the first region and the second region in a state where the street 23 has been irradiated with the first laser beam L1. Here, a region irradiated with the first laser beam L1 has an uneven shape (frosted glass shape) in a state where a part of the insulating film 24 has been removed by the first laser beam L1. Such an uneven surface has a low laser beam transmittance. Therefore, even in a case where the second laser beam L2 emitted after the irradiation with the first laser beam L1 is the laser beam having the processing energy for completely removing the insulating film 24 in the first region and the insulating film 24 in the second region, the uneven surface having the low transmittance can suppress passing light in a direction toward the semiconductor substrate 21 of the wafer 20 made of silicon or the like, and thermal damage of the wafer 20 caused by the laser beam can be suppressed. As described above, it is possible to suppress thermal damage of the wafer 20 caused by the laser beam can be suppressed and to suppress deterioration in chip quality by the laser processing method according to the present embodiment.

The second laser beam L2 may be a laser beam having processing energy for digging a part of the semiconductor substrate 21 included in the wafer 20 after the second step. As a result, a part of the semiconductor substrate 21 is dug by the second laser beam L2, and it is possible to suppress the occurrence of film peeling in the wafer 20 while reliably performing grooving processing of removing the surface layer.

The second laser beam L2 may be a laser beam having processing energy for carving the semiconductor substrate 21 by 4 μm or less after the second step. When the amount of digging is set to 4 μm or less, the thermal damage of the wafer 20 caused by the laser beam can be suppressed, and the deterioration in chip quality can be suppressed.

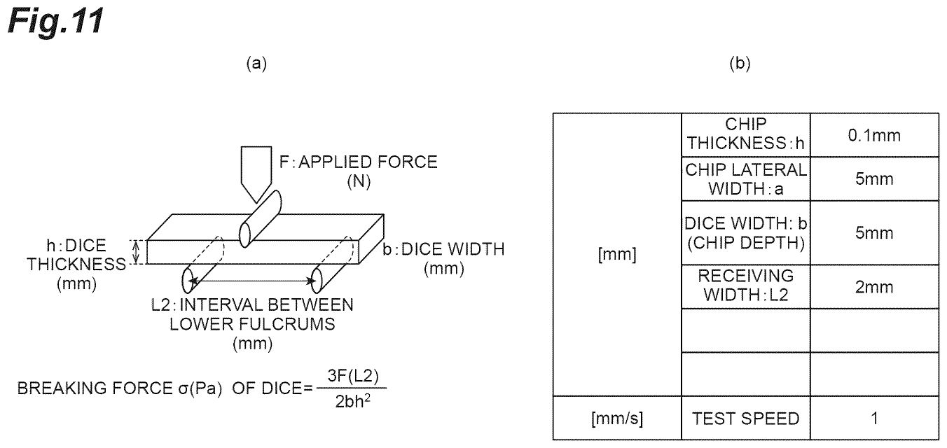

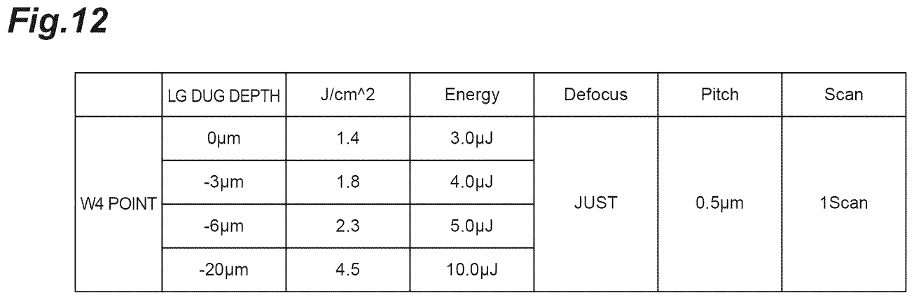

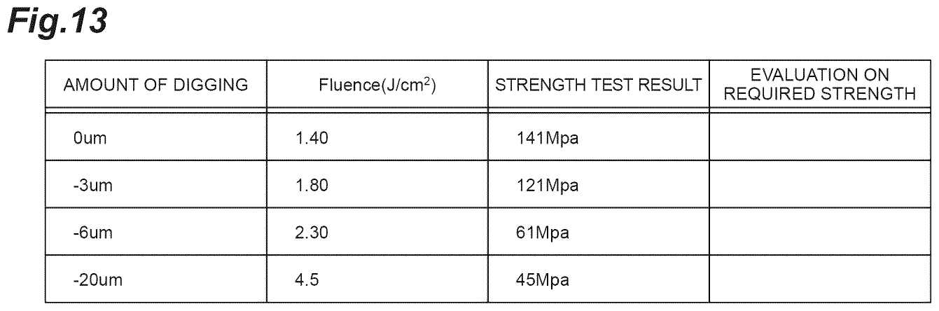

Here, results of a test performed to confirm the relationship between the amount of digging (depth of laser grooving) and chip strength will be described. FIGS. 11 and 12 are views illustrating conditions of the test regarding the relationship between the depth of laser grooving and the chip strength. FIG. 13 is a view illustrating results of the test regarding the relationship between the depth of laser grooving and the chip strength.

In this test, after the wafer 20 was ground to 100 μm, laser grooving was performed, then dicing was performed to obtain chips, and then a flexural strength test illustrated in FIG. 11(a) was performed to measure a chip strength. As illustrated in FIG. 11(a), in the flexural strength test, a device surface of a chip was disposed on a lower fulcrum side, a back surface of the chip was disposed on a side to which a force was applied, and a breaking stress σ when the force was applied to the chip was measured. When the applied force is F, an interval between two lower fulcrums is L2 (mm), a dice width is b (mm), and a dice thickness is h (mm), the breaking stress σ (Pa) is expressed by the following Formula (1).

$$Breaking stress σ ( Pa ) = 3 F ( L 2 ) / 2 bh 2 \qquad ( 1 )$$

In this test, as illustrated in FIG. 11(b), a chip thickness (dice thickness): h=0.1 mm, a chip lateral width: a=5 mm, a dice width: b=5 mm, a receiving width (interval between lower fulcrums): L2=2 mm, and a test speed was 1 mm/s. In addition, laser grooving conditions in this test were set as illustrated in FIG. 12. That is, a laser grooving width was set to 18 μm, the number of branch points was set to 4, and the amount of digging (depths of laser grooving) was set to be different from each other. As dicing conditions, a laser beam wavelength was 1080 nm, a processing speed was 180 mm/sec, an output was 0.12 W, and a pulse pitch was 2.3 μm.

As illustrated in the test results of FIG. 13, it has been confirmed that the chip strength relatively decreases as the amount of digging increases. In addition, as a result of comparing a required strength required in semiconductor manufacturing with the results, it has been found that the problem of product quality deterioration due to a decrease in the chip strength can be solved if the amount of digging can be suppressed up to 3 μm. As described above, it is necessary to dig the semiconductor substrate 21 by laser grooving from the viewpoint of suppressing the occurrence of film peeling, but it has been confirmed, from the above test results, that the influence of the HAZ is strongly generated and the chip strength is lowered when the semiconductor substrate is excessively dug.

The laser processing method according to the present embodiment includes the second step of irradiating the street 23 with the first laser beam L1 to make the insulating films 24 in the first region and the second region uneven, and the third step of irradiating the street 23 with the second laser beam L2 to completely remove the insulating films 24 in the first region and the second region after the second step.

In the laser processing method according to the present embodiment, the street 23 of the wafer 20 is irradiated with the first laser beam L1 to make the insulating films 24 in the first region and the second region uneven, and then, the street 23 is irradiated with the second laser beam L2 to completely remove the insulating films 24 in the first region and the second region. An uneven (frosted glass) surface of the insulating film 24 has a low laser beam transmittance. Therefore, even in a case where the second laser beam L2 is the laser beam having the processing energy for completely removing the insulating film 24 in the first region and the insulating film 24 in the second region, the uneven surface having the low transmittance can suppress the passing light in the direction toward the semiconductor substrate 21 of the wafer 20 made of silicon or the like, and thermal damage of the wafer 20 caused by the laser beam can be suppressed. As described above, it is possible to suppress thermal damage of the wafer 20 caused by the laser beam can be suppressed and to suppress deterioration in chip quality by the laser processing method according to the present embodiment.

### Modification

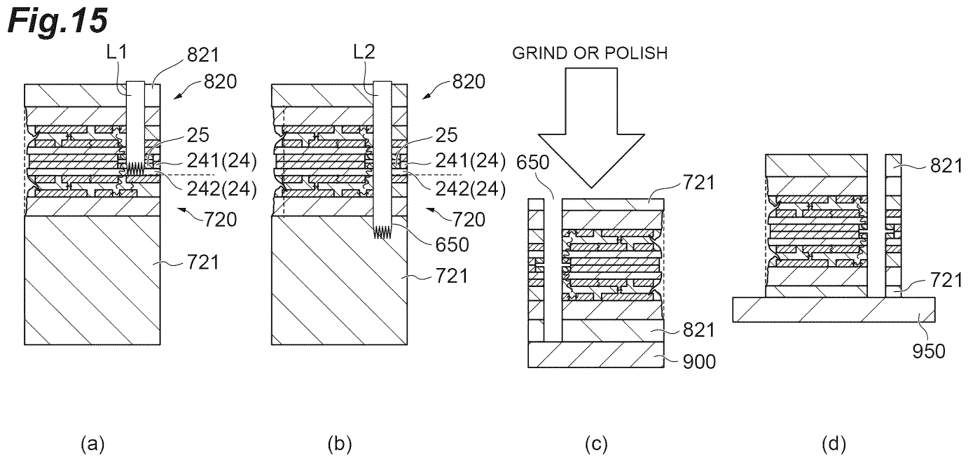

The present invention is not limited to the above embodiment. For example, the example in which the dicing is performed after the laser grooving has been described in the above embodiment, but the present invention is not limited thereto, and the dicing step may be omitted and full cutting may be performed by laser grooving processing. Hereinafter, a laser processing method in which a dicing step is omitted and full cutting is performed by laser grooving processing in a process of producing a bonded wafer will be described with reference to FIG. 15. Note that the bonded wafer will be described as an example, a laser processing method in which the dicing step is omitted and the full cutting is performed by the laser grooving may be performed on a single wafer other than the bonded wafer.

As illustrated in FIG. 15(a), the bonded wafer in which a wafer 720 on a lower surface side and a wafer 820 on an upper surface side are bonded together is prepared. The wafer 820 is ground or polished such that the semiconductor substrate 821 is 10 μm or less. In addition, the wafer 720 has an original thickness. A surface layer of a street of the wafer 720 has a region including the insulating film 24 and the metal structure 25 on the insulating film 24. As illustrated in FIG. 15(a), the street of the wafer 720 is irradiated with the first laser beam L1, so that the metal structure 25 is completely removed and a part of the insulating film 24 is removed. The first laser beam L1 enters from the semiconductor substrate 821 side of the wafer 820 and reaches the insulating film 24 of the wafer 720.

Subsequently, as illustrated in FIG. 15(b), the street of the wafer 720 is irradiated with the second laser beam L2, so that the insulating film 24 of the wafer 720 is completely removed. The laser beam L2 enters from the semiconductor substrate 821 side of the wafer 820 and digs a part of the semiconductor substrate 721 of the wafer 720. That is, the irradiation plane 650 of the second laser beam L2 reaches the semiconductor substrate 721. The amount of digging of the semiconductor substrate 721 by the second laser beam L2 is set as a range in which no HAZ is generated.

Subsequently, as illustrated in FIG. 15(c), a protective film 900 is attached to the semiconductor substrate 821 side of the wafer 820, and the semiconductor substrate 721 of the wafer 720 is ground or polished such that the irradiation plane 650 as a groove part is exposed.

Finally, as illustrated in FIG. 15(d), a tape 950 is attached to the semiconductor substrate 721 side of the wafer 720 to hold the chip. Expanding processing is performed as necessary, and chipping is performed.

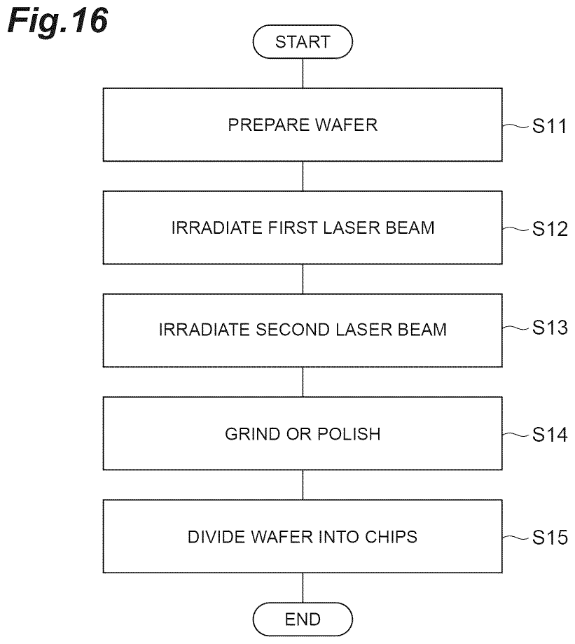

Next, the laser processing method according to the above-described modification will be described with reference to a flowchart of FIG. 16. First, a bonded wafer is prepared (step S11, a first step).

Subsequently, a street is irradiated with the predetermined first laser beam L1 (step S12, a second step). The first laser beam L1 is a laser beam having processing energy for removing a part of the insulating film 24 in the first region of the wafer 720 to leave the other part, completely removing the metal structure 25 in the second region of the wafer 720, and removing a part of the insulating film 24 in the second region to leave the other part in an irradiation range.

Subsequently, the street is irradiated with the predetermined second laser beam L2 (step S13, a third step). The second laser beam L2 is a laser beam having processing energy for completely removing the insulating film 24 in the first region and the insulating film 24 in the second region of the wafer 720 in the irradiation range. The grooving processing is completed by the third step.

Subsequently, the protective film 900 is attached to the semiconductor substrate 821 side of the wafer 820, and the semiconductor substrate 721 of the wafer 720 is ground or polished such that the irradiation plane 650 as a groove part is exposed (step S14). Finally, the wafer is divided into chips (step S15).

As described above, the laser processing method according to the modification further includes the fourth step of grinding or polishing the semiconductor substrate to expose the groove formed in the street by the irradiation with the second laser beam L2 after the irradiation with the second laser beam L2. According to such a laser processing method, full cutting can be performed by grooving processing without performing a dicing step after laser grooving. As a result, processing can be performed quickly.

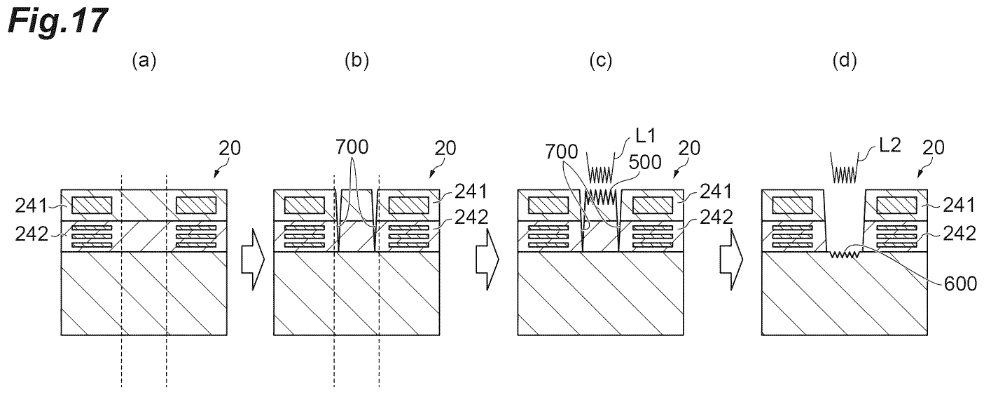

In addition, as another modification, for example, before performing the grooving processing, an isolation pass for forming narrow grooves at both ends of a portion to be grooved by the laser processing apparatus 1 may be performed. In the example illustrated in FIG. 17, the wafer 20 is prepared (see FIG. 17(a)), narrow grooves 700 are formed at both ends of a portion to be grooved (see FIG. 17(b)), and thereafter, the first laser beam L1 is emitted so as to form the frosted glass surface 500 (see FIG. 17(c)), and finally, the second laser beam L2 is emitted such that an irradiation plane 600 reaches a semiconductor substrate (see FIG. 17(d)).

As described above, a step of irradiating with the first laser beam L1 and a step of irradiating with the second laser beam L2 are steps of performing processing such that a dug depth in a device surface becomes uniform to suppress a decrease in strength due to the HAZ. Here, there is a case where film peeling occurs at both ends of the groove during laser grooving depending on a device type. In this respect, as in the above-described modification, the narrow grooves 700 are formed at both the ends of the portion to be grooved before the laser grooving is performed, and the laser grooving is performed after the narrow grooves 700 are formed, whereby the film peeling can be suitably suppressed while suppressing the HAZ.

In the above-described isolation pass (see FIG. 17(b)), a film can be appropriately removed while allowing the film to absorb a laser beam without excess or deficiency and suppressing film peeling, for example, by adjusting laser conditions using a burst pulse. Note that both ends need to be irradiated with the laser beam in the isolation pass, but the both ends may be cut at a time by branching the laser beam into two points. In addition, in a case where the influence of the HAZ is exerted also in the isolation pass, the influence of the HAZ can be suppressed by performing branching in a substantially single array shape and performing irradiation.

### REFERENCE SIGNS LIST

1 Laser processing apparatus
2 Support part
3 Irradiation unit
5 Control unit
20 Wafer
21 Semiconductor substrate
23 Street
24 Insulating film
25 Metal structure

1: A laser processing method comprising:
preparing a wafer including a plurality of functional elements disposed adjacent to each other across a street, the wafer having a first region in which a surface layer of the street includes an insulating film and a second region in which the surface layer includes an insulating film and a metal structure on the insulating film;
irradiating the street with a predetermined first laser beam; and
irradiating the street with a predetermined second laser beam after the irradiating the street with the predetermined first laser beam,
wherein the first laser beam is a laser beam having processing energy for removing a part of the insulating film in the first region to leave another part, completely removing the metal structure in the second region, and removing a part of the insulating film in the second region to leave another part in an irradiation range, and
the second laser beam is a laser beam having processing energy for completely removing the insulating film in the first region and the insulating film in the second region after the irradiating the street with the predetermined first laser beam in the irradiation range.

2: The laser processing method according to claim 1, wherein the second laser beam is a laser beam having processing energy for digging a part of the substrate included in the wafer after the irradiating the street with the predetermined first laser beam.

3: The laser processing method according to claim 2, wherein the second laser beam is a laser beam having processing energy for carving the substrate by 4 μm or less after the irradiating the street with the predetermined first laser beam.

4: The laser processing method according to claim 2, further comprising grinding or polishing the substrate to expose a groove formed in the street by irradiation with the second laser beam after the irradiating the street with the predetermined second laser beam.

5: A laser processing method comprising:
preparing a wafer including a plurality of functional elements disposed adjacent to each other across a street, the wafer having a first region in which a surface layer of the street includes an insulating film and a second region in which the surface layer includes an insulating film and a metal structure on the insulating film;
irradiating the street with a laser beam to make the insulating films in the first region and the second region uneven; and
irradiating the street with a laser beam to completely removing the insulating films in the first region and the second region after the irradiating the street with the laser beam to make the insulating films in the first region and the second region uneven.

6: A laser processing apparatus comprising:
a support part configured to support a wafer including a plurality of functional elements disposed adjacent to each other across a street, the wafer having a first region in which a surface layer of the street includes an insulating film and a second region in which the surface layer includes an insulating film and a metal structure on the insulating film;
an irradiator configured to irradiate the street with a laser beam; and
a controller configured to control the irradiator,
wherein the controller is configured to execute
first control of controlling the irradiator in such a manner that the street is irradiated with a predetermined first laser beam, and
second control that controls the irradiator in such a manner that the street is irradiated with a predetermined second laser beam after the first control,
the first laser beam is a laser beam having processing energy for removing a part of the insulating film in the first region to leave another part, completely removing the metal structure in the second region, and removing a part of the insulating film in the second region to leave another part in an irradiation range, and
the second laser beam is a laser beam having processing energy for completely removing the insulating film in the first region and the insulating film in the second region after the irradiation with the first laser beam in the irradiation range.

7: A laser processing apparatus comprising:
a support part configured to support a wafer including a plurality of functional elements disposed adjacent to each other across a street, the wafer having a first region in which a surface layer of the street includes an insulating film and a second region in which the surface layer includes an insulating film and a metal structure on the insulating film;
an irradiator configured to irradiate the street with a laser beam; and
a controller configured to control the irradiator,
wherein the controller is configured to execute
first control of controlling the irradiator in such a manner that the street is irradiated with the laser beam to make the insulating films in the first region and the second region uneven, and
second control of controlling the irradiator in such a manner that the street is irradiated with the laser beam to completely remove the insulating films in the first region and the second region after the first control.
